(19) United States
(12) Patent Application Publication
(10) Pub. No.: US 2015/0202680 A1
(43) Pub. Date: Jul. 23, 2015

(54) METHOD FOR MANUFACTURING SEMIFINISHED PRODUCT FOR HARD DISK DRIVE DEVICE CASE BODY AND SEMIFINISHED PRODUCT FOR CASE BODY

(71) Applicant: SHOWA DENKO K.K., Tokyo (JP)

(72) Inventor: Masahiro Sato, Kitakata-shi (JP)

(73) Assignee: SHOWA DENKO K.K., Tokyo (JP)

(21) Appl. No.: 14/413,585

(22) PCT Filed: Jul. 11, 2013
(86) PCT No.: PCT/JP2013/068999

§ 371 Date: Jan. 8, 2015

(30) Foreign Application Priority Data
Jul. 12, 2012 (JP) 2012-156979

(51) Int. Cl. B21J 5/02; B21J 13/02; H05K 5/04; G06F 1/18; H05K 5/03; C22C 21/02; B21J 1/06

(52) U.S. Cl. CPC B21J 5/025; C22C 21/02; B21J 13/02; B21J 1/06; G06F 1/181; H05K 5/03; H05K 5/04

(57) ABSTRACT

The present invention is to provide a method for manufacturing a case body of a hard disk drive device (HDD) case capable of not easily causing a defect in a thin portion, accurately forming a thin portion and a fine shape portion, and obtaining satisfactory rigidity, strength, machinability, joint performance, and airtightness. A forging material composed of an aluminum alloy is die-forged into an intermediate product having an intermediate shape and intermediate dimension by hot forging and the intermediate product is further die-forged into the shape of a semifinished product for a case body by cold forging. The intermediate product is rapidly cooled by heat extraction effect from a cold forging die when the intermediate product is charged into the cold forging die and cold-forged in a second forging step after being removed from a hot forging die.

### TECHNICAL FIELD

The present invention relates to a method for manufacturing an aluminum alloy semifinished product used for a case main body (case body) of a hard disk drive device such as a computer and particularly relates to a method for manufacturing a semifinished product by forging.

Priority is claimed on Japanese Patent Application No. 2012-156979, filed Jul. 12, 2012, the content of which is incorporated herein by reference.

### BACKGROUND ART

As is well known, a hard disk drive device is a device for reading data recorded on a magnetic disk (hard disk) having a disk shape and writing data. The hard disk drive device generally has a configuration in which various kinds of functional components for a hard disk and a hard disk drive, for example, functional components such as a motor such as a spindle motor for rotating a hard disk, a head for reading data from a disk surface of a hard disk and writing data, and an actuator for moving the position of the head, are housed in a case. The case of such a hard disk drive device is generally formed in a typical thin rectangular box shape. The case is typically configured with a case body (also referred to as a base) which is formed in a thin box-like shape with an opened upper surface, and a plate-like cover which closes the open side (upper surface) of the case body. A housing space which houses the hard disk and the functional components is defined and formed inside the case body (for example, refer to PTL 1).

As a typical example of the case body (base) in such a hard disk drive device case, a schematic example of the basic form thereof will be shown in FIGS. 1 to 3.

In FIGS. 1 to 3, a case body 1 is formed in a thin bottomed rectangular box shape in which the peripheral portions (four continuous sides) of a plate-like bottom portion 3 having a rectangular shape when viewed from a plane view stand in a direction parallel to the thickness direction of the bottom portion 3, a side wall portion (outer portion) 5 which continues in a rectangular annular shape is formed, and one surface (one surface in the direction parallel to the thickness direction of the bottom portion 3; upper surface in the example shown in the drawing) is opened as a whole. A housing space 6 which houses the hard disk and the functional components such as the motor, the head, and the actuator is defined and formed by the bottom surface 3 and the side wall portion (outer portion) 5.

On one side of the bottom surface 3 in the length direction, a large diameter boss portion 9 which corresponds to a hard disk mounting position is formed in a raised round and plate-like shape and further a small diameter boss portion 11 for mounting the motor is formed so as to protrude from the center of the large diameter boss portion 9. In addition, an air filter holding portion 13 which continues from the side wall portion 5 is formed near the corner portion of the bottom surface 3 (corner portion near the large diameter boss portion 9). Further, on the other side of the bottom surface 3 in the length direction, pins 7 which are screws for mounting the cover stand at a plurality of positions. In an actual case product, either finer shapes are imparted to each portion or a fine convex or concave portion other than the above is typically formed, but only basic portions are shown and detailed shapes are omitted herein.

On the other hand, the cover of the hard disk drive device case is not particularly shown. However, the cover maybe formed in, for example, a simple plate-like rectangular shape. The cover is placed on the open side of the case body 1 and is mounted on the case body 1 using the pins 7. Further, the space is sealed with a sealing member such as a gasket between the peripheral portion of the cover and the upper edge surface of the side wall portion 5 of the case body 1, and the housing space 6 of the case body 1 is sealed.

In the case body 1 of this type of hard disk drive device, a thick portion and a thin portion are complicated and further the thickness difference between the thickest portion and the thinnest portion is typically large. Here, the thickness of the case body 1 refers to a dimension in a direction orthogonal to the plate surface of the bottom surface 3 (that is, a direction parallel to the thickness direction of the bottom surface 3).

In the general case body 1, a portion whose thickness is largest is the side wall portion 5 and a portion whose thickness is smallest is the bottom surface 3. The thickness of each portion in the actual case body 1 differs depending on products, but the thickness tb of the bottom surface 3 is generally about 30% or less of the thickness to of the side wall portion 5. Further, as a typical specific dimensional example, the thickness ta of the thickest side wall portion 5 is about 5 mm and the thickness tb of the thinnest bottom surface 3 is about 0.7 mm. In this case, the ratio of the thickness tb to the thickness ta is 14%.

Excellent airtightness is required for this type of hard disk drive device case so that dust or moisture does not enter from the outside. In order to maintain good airtightness, a case which is not easily deformable and has high rigidity is required.

Further, it is necessary to increase the mounting accuracy of each component configuring the hard disk drive device. In order to increase the mounting accuracy, it is desired that the dimensional accuracy of each portion in the case is increased. In order to increase the dimensional accuracy, the material for the case requires excellent formability, excellent cutting performance in final finishing or the like, and high strength in order to stably maintain a fine shape and further requires good joint performance when each component is mounted.

Additionally, good heat dissipation (thermal conductivity) is demanded from the viewpoint of preventing thermal deformation, and light weight is further emphasized from the viewpoint of a weight reduction of an electronic component.

Due to the required characteristics, an aluminum alloy is generally used for the case body and the cover of the hard disk drive device case.

The aluminum alloy case body of this type of hard disk drive device case is typically obtained by directly casting a semifinished product from a molten aluminum alloy using die-casting, and subjecting the die cast semifinished product to appropriate finishing such as cutting so as to finish a case body (for example, refer to PTLs 1 and 2).

### CITATION LIST

### Patent Literature

[PTL 1] Japanese Unexamined Patent Application, First Publication No. 3-207059

[PTL 2] Published Japanese Translation No. 2010-528400 of the PCT International Publication

### SUMMARY OF INVENTION

### Technical Problem

In a hard disk drive device case, particularly, a case body, a thick portion and a thin portion are complicated as described above and further the difference of the thickness between the thick portion and the thin portion is large. Therefore, when the case body is manufactured by die-casting, at the injection of a molten aluminum alloy into a die for die-casting, the molten aluminum alloy does not extend sufficiently to the thin portion and thus the thin portion is defective or a fine shaped portion cannot be formed accurately in many cases. In this case, the dimensional accuracy and the strength of the thin portion and the fine shaped portion are lowered and as a result, a problem occurs in that airtightness as a hard disk drive device case is deteriorated or the non-defective yield is lowered. In addition, when the case body is manufactured by die-casting, the component composition of an aluminum alloy as a material has to be selected mainly from the viewpoint of fluidity at die-casting. Therefore, the above-described characteristics required for the case body, particularly, the strength and the rigidity are in fact not satisfied in many cases.

The present invention is made under the above circumstances and an object thereof is to provide a method for manufacturing an aluminum alloy case body of a hard disk drive device case capable of not easily causing a defect in a thin portion, accurately forming a thin portion and a fine shape portion at a high dimensional accuracy, and sufficiently satisfying characteristics required for the hard disk drive device case body such as rigidity, strength, machinability, joint performance, and airtightness, as a case body of a hard disk drive device case, and an aluminum alloy case body manufactured by the method.

### Solution to Problem

In order to solve the above-described problems, as a result of repeatedly conducting various experiments and investigations on the method for manufacturing an aluminum alloy case body, the present inventors have found that it is optimum to apply forging to the method, and even in this case, it is not appropriate to singly perform either of hot forging or cold forging, but it is appropriate to forge the material into an intermediate product having a schematic shape by hot forging and further forge the intermediate product by cold forging to finish the material into a semifinished product, and further, even in this case, it is appropriate to perform rapid cooling by heat extraction effect from a cold forging die by performing the second cold forging immediately after performing the first hot forging. Thus, the present invention has been accomplished.

In order to achieve the above-described object, the present invention provides each aspect described in the following (1) to (11).
(1) A method for manufacturing an aluminum alloy semifinished product for a hard disk drive device case body having a box-like shape with one open side, the method comprising:

a first forging step of hot die forging a forging material composed of an aluminum alloy to an intermediate product using a hot forging die;

a transfer step of removing the intermediate product from the hot forging die after the first forging step ends and transferring the intermediate product to a position of a cold forging die to be charged into the cold forging die; and

a second forging step of cold die forging the intermediate product into a shape of a semifinished product for a hard disk drive device case body,

wherein while the intermediate product is charged into the cold forging die and cold-forged from the transfer step to the second forging step, the intermediate product is rapidly cooled to a cold forging temperature by heat extraction effect from the cold forging die.

In (1), the term “semifinished product” refers to a product which has been subjected to machining (cutting or polishing of a part of the surface) in order to finally finish the material into a case body product to be used for a hard disk drive device case, machining such as punching for mounting a hard disk or each functional component of a drive device, and plastic working performed as a previous stage before other surface treatment is performed.

Here, when the shape of the semifinished product for a hard disk drive device case body is die-forged only by hot forging, a load of a portion for forming a thin portion and a fine shape portion of the case body is extremely increased in the die. That is, as described above, there is a large difference between the thickness of a thick portion and a thin portion of the hard disk drive device case body has, and a fine shaped portion has to be formed at a high dimensional accuracy in order for each component of the hard disk drive device to be mounted with a high degree of accuracy. However, it is difficult to form the thin portion and the fine shaped portion with a high level of accuracy using only hot forging, and local deformation of the material is increased and the amount of heat generated during working is increased in these portions. As a result, for example, even when the temperature of the material is appropriately adjusted, local melting occurs due to heat generated during working, and thus, there is a concern of die seizure or local embrittlement of the material occurring.

In contrast, as described in (1), when a two-stage forging method in which cold forging is further performed after hot forging is performed, it is preferable that the intermediate product be formed in the stage of hot forging to have a shape and dimension close to the shape of the semifinished product to be obtained to some degree and then be formed into the semifinished product having a required shape in the cold forging. Thus, the amount of a load on the thin portion and the fine shaped portion during the hot forging is decreased and the above-described problem can be avoided. In addition, since the intermediate product is rapidly cooled by heat extraction effect from the cold forging die when the intermediate product is charged into the cold forging die and cold-forged in the second forging step after being removed from the hot forging die, the intermediate product does not need to be cooled by separate cooling means after the hot forging and before the cold forging and thus the facility cost is reduced compared to a case in which separate cooling means is provided. Further, since cold forging is performed immediately after the hot forging without a time interval, the production efficiency can be improved. Further, in the case of using an alloy in which age hardening can be expected as an aluminum alloy material, when the material is rapidly cooled by heat extraction effect from the cold forging die after the hot forging, solid-solution of an element contributing to age hardening is facilitated, that is, so-called solutionizing is facilitated. Thus, higher strength can be achieved by natural aging or artificial aging after the cold forging.

Here, the terms “thick” and “thin” refer to, when a thickness dimension of a cross section in a direction orthogonal to a plate surface of a surface opposite to the open side (bottom portion) in the semifinished product for a case body having a box-like shape is defined as a thickness, the length in the thickness direction of the cross section.

(2) The method for manufacturing an aluminum alloy semifinished product for a hard disk drive device case body according to (1),

wherein when a solidus temperature of the aluminum alloy as the forging material is T° C., the hot forging in the first forging step is performed at a temperature within a range of [T−100]° C. to [T−50° C.] and the cold forging in the second forging step is performed at a temperature of 80° C. or lower, and an average cooling rate from [T−100]° C. to 80° C. or lower in a cooling process from the transfer step to the second forging step after the first forging step ends is 50° C./sec or more.

As described in (2), as long as the temperature condition of the hot forging in the first forging step is determined and the cooling condition in the following cooling process by heat extraction effect from the cold forging die is determined, when an alloy in which age hardening can be expected as described above is used as an aluminum alloy material, solid-solution of an element contributing to age hardening is facilitated in the hot forging-cooling process, that is, so-called solutionizing is facilitated. Thus, higher strength can be achieved by natural aging or artificial aging after the cold forging.

(3) The method for manufacturing an aluminum alloy semifinished product for a hard disk drive device case body according to (1) or (2),

wherein the cold forging die is cooled to 80° C. or lower in at least in the transfer step and the second forging step.

(4) The method for manufacturing an aluminum alloy semifinished product for a hard disk drive device case body according to any one of (1) to (3),

wherein the semifinished product for a case body to be manufactured has a thin plate-like flat bottom portion and a side wall portion which stands from an edge portion of the bottom portion to one side with respect to the plate surface of the bottom portion, and a recessed space defined by the bottom portion and the side wall portion is a housing space for housing a hard disk and functional components of a hard disk drive device,

the thickness of at least a part of the plate-like material is reduced in the first forging step to form an intermediate concave portion to become the housing space, and

the thickness of the bottom surface of the intermediate concave portion is further reduced in the second forging step to form the housing space.

(5) The method for manufacturing an aluminum alloy semifinished product for a hard disk drive device case body according to (4),

wherein when the thickness dimension of the semifinished product to be manufactured in a direction orthogonal to the plate surface of the bottom portion thereof is t₂ and the dimension of the side wall portion in the same direction is ta, the condition of t₂≦0.3×ta is satisfied.

(6) The method for manufacturing an aluminum alloy semifinished product for a hard disk drive device case body according to (5),

wherein when the thickness of the material is t₀,

the thickness of the bottom portion of the intermediate concave portion in the intermediate product after the first forging step ends is t₁,

the thickness of the bottom portion of the semifinished product which has been subjected to the second forging step (cold forging) is t₂, and further

Δt₁=t₀−t₁, and

Δt₀=t₀−t₂,

the condition of Δt₁≧0.8×Δt₀ is satisfied and

the condition of Δt₁/t₀≧0.6 is also satisfied.

(7) The method for manufacturing an aluminum alloy semifinished product for a hard disk drive device case body according to any one of (1) to (6),

wherein hot forging is performed by applying back pressure to at least a part of the forging material in the first forging step.

Here, it is preferable that a portion to become a thick portion in the intermediate product which has been subjected to hot forging, for example, a portion to become the side wall portion be selected as a portion to which back pressure is applied at the hot forging in the first forging step, and back pressure not be applied to a portion to become a thin portion, for example, a portion to become the bottom portion. That is, in the hard disk drive device case body which is an object to be manufactured in the present invention, a thick portion and a thin portion are complicated and the thickness difference between the thickest portion and the thinnest portion is large. However, while back pressure is applied to the portion to become a thick portion, the back pressure is not applied to the thin portion. While the thin portion or the fine shaped portion associated with the thin portion is formed with a high level of accuracy, the thick portion can have a sufficient thickness. Further, in this case, compared to a case in which the back pressure is not applied, a high level of accuracy can be obtained with a small forging load.

(8) The method for manufacturing an aluminum alloy semifinished product for a hard disk drive device case body according to any one of (1) to (7),

wherein an Al—Si eutectic alloy including Si: 5% to 12% (mass %, the same applies hereafter), Fe: 0.1% to 1.0%, Cu: less than 1.0%, Mg: 0.3% to 1.5%, and a balance consisting of Al and unavoidable impurities is used as the aluminum alloy of the forging material.

In such an Al—Si eutectic alloy, an element such as Mg is solid-solved (solutionized) by rapid cooling after the first forging step by hot forging so that high strength and rigidity can be secured by natural aging or artificial aging after the second forging. Further, in addition to high strength and rigidity, the forgeability, machinability, and weldability are excellent. Therefore, the Al—Si eutectic alloy is most suitable for the material for the hard disk drive device case body of the present invention.

(9) The method for manufacturing an aluminum alloy semifinished product for a hard disk drive device case body according to any one of (1) to (7),

wherein one alloy selected from a 6000 series alloy, 7000 series alloy, and 2000 series alloy is used as the aluminum alloy of the forging material.

In the 6000 series alloy, 7000 series alloy, and 2000 series alloy, an element such as Mg is also solid-solved (solutionized) by rapid cooling after the first forging step by hot forging like the above-described Al—Si eutectic alloy so that high strength and rigidity can be secured by natural aging or artificial aging after the second forging.

(10) The method for manufacturing an aluminum alloy semifinished product for a hard disk drive device case body according to any one of (1) to (7),

wherein a 1000 series alloy is used as the aluminum alloy of the forging material.

When the 1000 series alloy (pure aluminum alloy) is used, crystal grains are refined by rapid cooling after the first forging using hot forging and thus relatively high strength and rigidity can be obtained.

(11) An aluminum alloy semifinished product for a hard disk drive device case body which is manufactured by the method according to any one of (1) to (10).

### Advantageous Effects of Invention

According to the method for manufacturing an aluminum alloy semifinished product for a hard disk drive device case body of the present invention, it is possible to reliably and easily obtain an aluminum alloy semifinished product for a case body, capable of not easily causing a defect in a thin portion, accurately forming a thin portion and a fine shape portion at a high dimensional accuracy, and further sufficiently satisfying characteristics required for the hard disk drive device case body such as rigidity, strength, machinability, joint performance, and airtightness, as a semifinished product of a case body used for the hard disk drive device case.

### BRIEF DESCRIPTION OF DRAWINGS

FIG. 1 is a perspective view schematically showing an example of an aluminum alloy case body for a hard disk drive device to be obtained by a method of the present invention.

FIG. 2 is a vertical cross-sectional view taken along line II-II of FIG. 1.

FIG. 3 is a vertical cross-sectional view taken along line of FIG. 1.

FIG. 4 is a schematic exploded view showing an embodiment of the method for manufacturing an aluminum alloy semifinished product for a hard disk drive device case body of the present invention.

FIG. 5 is a schematic exploded view showing a dimensional change of a material in each stage in the embodiment of the method for manufacturing an aluminum alloy semifinished product for a hard disk drive device case body of the present invention.

FIG. 6 is a schematic exploded view showing another embodiment of the method for manufacturing an aluminum alloy semifinished product for a hard disk drive device case body of the present invention.

FIG. 7 is a vertical cross-sectional view showing an example of a hot forging die used in a first forging step in a state in which an upper die is positioned at a top dead center (die open state) in the method for manufacturing an aluminum alloy semifinished product for a hard disk drive device case body of the present invention.

FIG. 8 is a vertical cross-sectional view showing an example of the hot forging die shown in FIG. 7 in a state in which the upper die is positioned at a bottom dead center (die closed state).

FIG. 9 is a perspective view showing an example of a lower die for cold forging used in a second forging step in the method for manufacturing an aluminum alloy semifinished product for a hard disk drive device case body of the present invention.

### DESCRIPTION OF EMBODIMENTS

Hereinafter, embodiments of a method for manufacturing an aluminum alloy semifinished product for a hard disk drive device case body of the present invention will be described in detail. Of course, the embodiments shown below are merely exemplary and the present invention is not limited to these embodiments. In addition, in the drawings used in the following description, in order to facilitate understanding of features, the characteristic portions may be enlarged or detailed uncharacteristic portions may be omitted for convenience, and the dimensional ratios and the like of the respective components are not necessarily the same as the actual ones. Further, in the following description, materials, dimensions, and the like are merely exemplary, and do not limit the present invention, and can be appropriately modified within a range not departing from the scope of the present invention.

First, an aluminum alloy used as a forging material in the manufacturing method of the present invention will be described.

### [Material Aluminum Alloy]

A material (forging material) for a semifinished product for a hard disk drive device case body is not particularly limited as long as the material is a forgeable aluminum alloy. However, in the case of the method of the present invention, a solutionizing effect can be expected by rapid cooling by heat extraction effect from a cold forging die when a hot-forged product (intermediate product), which has been subjected to a first forging step (hot forging), is subjected to cold forging of a second forging step. Here, it is preferable to select an aluminum alloy capable of facilitating hardening by age precipitation (age hardening) as the aluminum alloy material. That is, an aluminum alloy strengthened through the use of an aluminum alloy containing elements contributing to age hardening, age-hardened through the positive use of solid-solving elements, solutionized by rapid cooling in a transfer step after the first forging step, and then precipitated by natural aging (or artificial aging depending on the case) is preferably selected to be used as the material for the hard disk drive device case body.

As such an aluminum alloy capable of achieving high strength by solutionizing-aging and suitable for forging, various aluminum alloys are known in the related art. Examples thereof include an Al—Si eutectic alloy, especially, an “AHS” alloy (registered trademark) having an Al—Si—Cu—Mg-based alloy composition as a basic component. Examples thereof further include so-called 6000 series Al—Mg—Si-based alloys, 7000 series Al—Zn—Mg-based alloys, or Al—Zn—Mg—Cu-based alloys, and further, 2000 series Al—Cu-based alloys. All of these examples can be used as the material for the case of the present invention.

The above-mentioned “AHS” is a registered trademark of an aluminum alloy for high strength and high wear resistance use available from Showa Denko Kabushiki Kaisha.

In addition, the 6000 series alloy refers to an alloy having the first number starting with “6” as a four-digit alloy number in standards such as the JIS standards in Japan, the AA standard in the U.S, and the DIN standard in German. In addition, the 7000 series alloy and the 2000 series alloy refer to alloys respectively having the first numbers starting with “7” and “2” as four-digit alloy numbers in the same standard.

However, the aluminum alloy used as the material for the case body in the present invention is not limited to an alloy capable of achieving high strength by solutionizing-aging and in a case in which high strength and high rigidity are not particularly required, for example, a 1000 series alloy, that is, a pure aluminum alloy may be allowed to be used.

Next, the above-described respective series of aluminum alloys will be described in detail.

### <Al—Si Eutectic Alloy>

The Al—Si eutectic alloy represented as the aforementioned “AHS” alloy is an alloy in which eutectic Si particles are crystallized in a matrix. It is preferable that the alloy contains as the component composition thereof, Si: 5% to 12% (mass %, the same applies hereafter), Fe: 0.1% to 1.0%, Cu: less than 1.0% (including 0%), Mg: 0.3% to 1.5%, and a balance consisting of Al and unavoidable impurities. In such an Al—Si eutectic alloy, as described above, an element such as Mg is solid-solved (solutionized) by rapid cooling in the transfer step for the second forging step after the first forging step by hot forging and high strength and rigidity can be secured by natural aging or artificial aging after the second forging step. Additionally, since the forgeability is excellent and the machinability and the weldability are also excellent, the alloy is suitable for the material for the hard disk drive device case body of the present invention.

The reason for limiting a preferable component composition of the Al—Si eutectic alloy to the above-described composition is as follows.

Si

Si is distributed in the matrix as eutectic Si and improves the rigidity to improve the strength of the aluminum alloy by precipitating Mg₂Si particles when Si coexists with Mg. In addition, when the eutectic Si particles are dispersed in the matrix, good chip partibility is obtained and the free machinability is improved. When the amount of Si is less than 5%, these effects cannot be sufficiently obtained. On the other hand, when the amount of Si is more than 12%, the initial Si is crystallized and thus the forgeability is deteriorated. The amount of Si is preferably within a range of 5% to 12%. Even when the amount of Si is within a range of 5% to 12%, the amount of Si is more preferably in a range of 9% to 12%, and still more preferably within a range of 10% to 11%.

The particle size of the eutectic Si particle is preferably 8 μm or less. When the particle size of the eutectic Si particle is more than 8 μm, the forgeability is deteriorated. The particle size of the eutectic Si particle is preferably within a range of 0.4 μm to 5.5 μm, and still more preferably within a range of 0.8 μm to 5.5 μm. Here, the sentence “the particle size of the eutectic Si particle is 8 μm or less, or within a range of 0.4 μm to 5.5 μm, or within a range of 0.8 μm to 5.5 μm” means that the actual particle distribution is within the ranges and for example, the number of eutectic Si particles of 95% or more, and preferably 98% or more, of all eutectic Si particles, measured by image processing of a microscopic structure observation image magnified by about 400 times, are within the ranges.

Fe

Fe allows Al—Fe-based or Al—Fe—Si-based particles to be precipitated and allows recrystallized particles to be refined at the first forging (hot forging) to improve the forging workability in the following second forging (cold forging) step. Thus, the alloy can be easily processed into a complicated and fine shape. When the amount of Fe is less than 0.1%, the effect is small. On the other hand, when the amount of Fe is more than 1.0%, the amount of Al—Fe-based or Al—Fe—Si-based coarse crystallized particles is increased, which causes a deterioration in forgeability. Therefore, the amount of Fe is preferably within a range of 0.1% to 1.0%. The amount of Fe is preferably 0.1% to 0.5%, and more preferably 0.21% to 0.3%.

Cu

When Cu is contained in the alloy, Cu allows CuAl₂ particles to be precipitated and contributes to improving the strength of the aluminum alloy. When the amount of Cu is 1% or more, the forgeability is deteriorated. Thus, the amount of Cu is preferably less than 1%. The amount of Cu is more preferably 0.9% or less, and still more preferably less than 0.5%. However, Cu may not be substantially contained. That is, the amount of Cu may be 0%, or a trace amount of Cu may be contained as an unavoidable impurity.

Mg

When Mg is contained in the alloy, Mg allows Mg₂Si particles to be precipitated when Mg coexists with Si and contributes to improving the strength of the aluminum alloy. When the amount of Mg is less than 0.3%, the effect of improving the strength is small. On the other hand, when the amount of Mg is more than 1.5%, the forgeability is deteriorated. Therefore, the amount of Mg is preferably within a range of 0.3% to 1.5%. Further, the amount of Mg is more preferably within a range of 0.4% to 1.0%.

Balance

In the Al—Si eutectic alloy, a balance of each element of Si, Fe, Cu, and Mg may be basically composed of Al and unavoidable impurities, but may further contain one or two or more elements of Mn: 0.1% to 1% (preferably 0.2% to 0.4%), Cr: 0.04% to 0.3% (preferably 0.15% to 0.25%), Zr: 0.04% to 0.3% (preferably 0.1% to 0.2%), and V: 0.01% to 0.1% (preferably 0.05% to 0.1%), in addition to the above-described elements. When these elements are added, the Al—Mn-based, Al—Mn—Fe—Si-based, Al—Cr-based, Al—Cr—Fe—Si-based, Al—Zr-based, or Al—V-based particles are precipitated and recrystallized particles are refined at the first forging (hot forging). Thus, the forging workability in the following second forging (cold forging) step is improved. Therefore, the alloy can be more easily processed into a complicated and fine shape.

The above-described Al—Si eutectic alloy may further contain one or two or more of Ti: 0.01% to 0.3% (preferably 0.01% to 0.2%, and more preferably 0.002% to 0.1%), B: 0.0001% to 0.05% (preferably 0.005% to 0.1%), and Sr: 0.001% to 0.2% (preferably 0.005% to 0.1%, and more preferably 0.005% to 0.05%). When Ti and B are added, the ingot structure is refined and the formation of ingot cracks during forging is reduced, and the forgeability is improved. In addition, when Sr is added, the eutectic Si is refined so that the forgeability can be improved.

### <6000 Series Alloy>

On the other hand, in the manufacturing method of the present invention, when a 6000 series alloy is used as a forging material, the alloy can be appropriately selected from 6xxx alloys defined in standards such as the its standards, the AA standards, the DIN standards, and the ISO standards, for example, alloys such as JIS 6061 alloy, JIS 6063 alloy, JIS 6082 alloy, JIS 6060 alloy, and JIS 6N01 alloy. In the present invention, for example, an alloy including Si: 0.3% to 1.0%, Cu: 0.2% to 0.6%, Mg: 0.8% to 1.5%, Cr: 0.14% to 0.3%, Mn: 0.14% to 0.3%, Fe: 0.18% to 0.50%, and a balance consisting of Al and unavoidable impurities is preferably used.

A preferable component composition of the 6000 series alloy to be used in the present invention will be described below.

Si

Si forms Mg₂Si precipitates when Si coexists with Mg and contributes to improving the strength of the case body as a final product. When the amount of Si is less than 0.3%, the effect of precipitation strengthening is reduced. On the other hand, when the amount of Si is more than 1.0%, the amount of intergranular precipitates of Si is increased and intergranular embrittlement easily occurs. Thus, the toughness of the final product is deteriorated. Therefore, the amount of Si is preferably within a range of 0.3% to 1.0%.

Cu

Cu increases the apparent supersaturated amount of Mg₂Si precipitates and increases the amount of Mg₂Si precipitates to accelerate age hardening of the final product. However, when the amount of Cu is less than 0.2%, the effect is not sufficiently obtained. On the other hand, when the amount of Cu is more than 0.6%, the corrosion resistance is deteriorated. Thus, the amount of Cu is preferably within a range of 0.2% to 0.6%.

Mg

Mg forms Mg₂Si precipitates when Mg coexists with Si and contributes to improving the strength of the case body as a final product. When the amount of Mg is less than 0.8%, the effect of precipitation strengthening is small. On the other hand, when the amount of Mg is more than 1.5%, the toughness of the final product is deteriorated. Thus, the amount of Mg is preferably within a range of 0.8% to 1.5%.

Cr

Cr is crystallized as an AlCrSi phase and uncrystallized Cr is precipitated to contribute to suppressing recrystallization. However, when the amount of Cr is less than 0.14%, the aforementioned effect is reduced. On the other hand, when the amount of Cr is more than 0.3%, a giant intermetallic compound is formed and the alloy may be embrittled. Thus, the amount of Cr is preferably within a range of 0.14% to 0.3%.

Mn

Mn is crystallized as an AlMnSi phase and uncrystallized Mn is precipitated to contribute to suppressing recrystallization. However, when the amount of Mn is less than 0.14%, the aforementioned effect is reduced. On the other hand, when the amount of Mn is more than 0.3%, a giant intermetallic compound is formed and the alloy may be embrittled. Thus, the amount of Mn is preferably within a range of 0.14% to 0.3%.

Fe

Fe is crystallized as an AlFeSi phase and prevents crystal grains from being coarsened to reduce the quenching sensitivity. Further, Fe improves the strength and the toughness so as to contribute to improving the corrosion resistance. However, when the amount of Fe is less than 0.18%, the effect is reduced. On the other hand, when the amount of Fe is more than 0.50%, the effect cannot be obtained. Therefore, the amount of Fe is preferably within a range of 0.18% to 0.50%.

Balance

In addition, basically, it is preferable that the balance be composed of Al and unavoidable impurities. However, in order to improve the strength, the balance may contain one or two or more selected from Zn: 0.05% to 0.20%, Ni: 0.05% to 0.15%, and Zr: 0.05% to 0.15%.

Further, as in the case of the aforementioned Al—Si eutectic alloy, one or two or more of Ti: 0.01% to 0.3% (preferably 0.01% to 0.2%, and more preferably 0.002% to 0.1%), B: 0.0001% to 0.05% (preferably 0.005% to 0.1%), and Sr: 0.001% to 0.2% (preferably 0.005% to 0.1%, and more preferably 0.005% to 0.05%) may be contained in the 6000 series alloy to improve the forgeability through refining of the ingot structure or refining of the Al—Si eutectic particles.

### <7000 Series Alloy>

In the manufacturing method of the present invention, when a 7000 series alloy is used as a forging material, the alloy can be appropriately selected from 7xxx alloys defined in standards such as the JIS standards, the AA standards, the DIN standards, and the ISO standards, for example, alloys such as JIS 7001 alloy, JIS 7050 alloy, JIS 7075 alloy, JIS 7475 alloy, and JIS 7N01 alloy. In the present invention, for example, an alloy including Zn: 3% to 10%, Mg: 1.0% to 3.0%, Si: 0.5% or less, Fe: 1.5% or less, and a balance consisting of Al and unavoidable impurities, or an alloy further containing Cu: 0.2% to 2.6%, in addition to the above elements, is preferably used.

### <2000 Series Alloy>

In the manufacturing method of the present invention, when a 2000 series alloy is used as a forging material, the alloy can be appropriately selected from 2xxx alloys defined in standards such as the JIS standards, the AA standards, the DIN standards, and the ISO standards, such as, for example, JIS 2014, JIS 2017, JIS 2024, JIS 2218, and JIS 2618. In the present invention, for example, an alloy including Cu: 1.5% to 5.0%, Mg: 0.2% to 1.8%, Si: 0.2% to 1.2%, Fe: 1.5% or less, and a balance consisting of Al and unavoidable impurities, or an alloy further containing Mn: 0.3% to 1.2%, in addition to the above elements, is preferably used.

### <1000 Series Alloy>

Further, when a pure aluminum alloy is used as the material for the hard disk drive device case of the present invention, the alloy can be appropriately selected from 1xxx alloys defined in standards such as the JIS standards, the AA standards, the DIN standards, and the ISO standards, such as, for example, JIS 1050, JIS 1100, JIS 1060, JIS 1200, and JIS 1N00. In this case, in the present invention, for example, an alloy including Fe: limited to 1% or less, Si: limited to 0.5% or less, Mn: limited to 0.05% or less, and a balance consisting of Al and other unavoidable impurities is preferably used.

### [Outline of Manufacturing Method]

When the method for manufacturing a semifinished product for a hard disk drive device case body of the present invention is performed, a plate-like forging material composed of the above-described aluminum alloy is subjected to first forging by hot die forging, and forged and formed into an intermediate product having a shape and dimension close to the shape and dimension of the semifinished product of the case body to some degree. Subsequently, the intermediate product is removed from the hot forging die and the intermediate product is immediately transferred to a position of a cold forging die to be charged into the cold forging die. Then, the intermediate product is subjected to second forging by cold die forging and finished into a semifinished product for a hard disk drive device case body. Here, when the intermediate product is charged into the cold die forging die and subjected to the second forging by cold forging after the first forging ends, as described above, the intermediate product is rapidly cooled by heat extraction effect from the cold forging die.

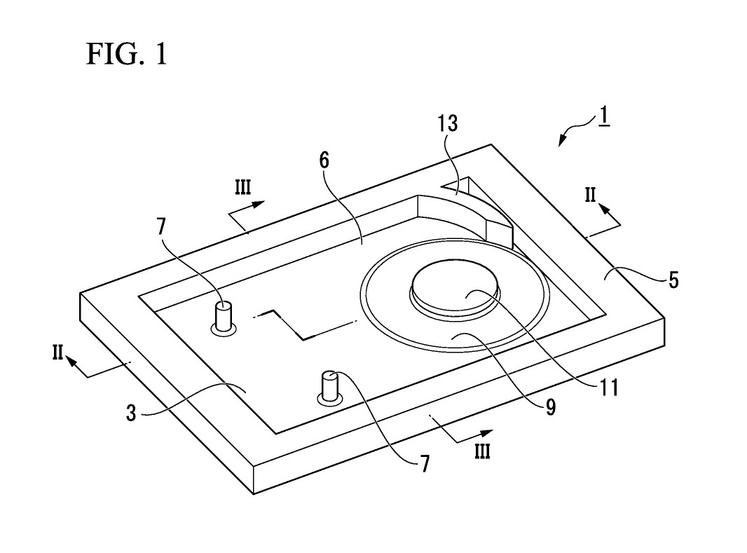

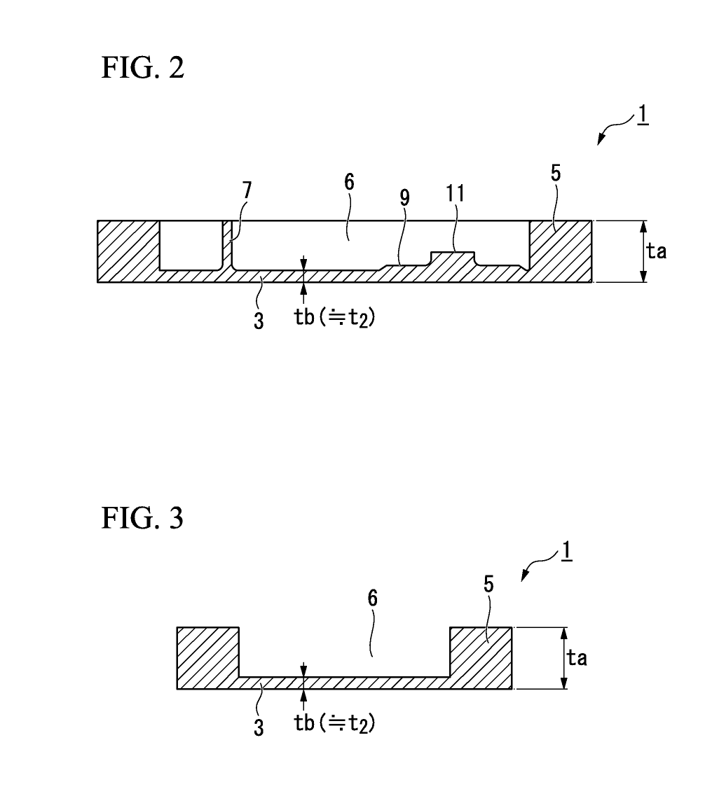

A schematic example of the shape of the semifinished product for a case body to be manufactured is a shape close to the shape of the case body described herein with reference to FIGS. 1 to 3. That is, the shape and dimension in which the intermediate product can be finished into the case body by finishing such as final cutting are adopted. In the following description, the case body shown in FIGS. 1 to 3 is considered as the semifinished product for a case body, and the same name and numeral references are assigned to respective portions of the semifinished product for a case body as those of the respective portions of the case body in FIGS. 1 to 3 for ease of explanation.

Basically, for example, the semifinished product for a case body has a thin flat bottom portion 3 which has a long rectangular plate-like shape and a side wall portion (outer portion) 5 which stands from the edge portion of the bottom portion 3 to one side with respect to the plate surface of the bottom portion and continues in a rectangular annular shape, and a recessed space 6 which is defined by the bottom portion and the side wall portion corresponds to a housing space for housing a hard disk and functional components of a hard disk drive device.

In addition, for example, a target dimension of each portion of the semifinished product for a case body to be manufactured also has a ratio of the thickness tb of the thinnest bottom portion 3 to the thickness ta of the thickest side wall portion 5 is preferably 30% or less as in the description of the case body as referred to in FIGS. 1 to 3.

That is, the following expression is preferably satisfied.

t₂≦0.3×ta

As a typical specific example, the thickness ta of the thickest side wall portion 5 is about 5 mm and the thickness tb of the thinnest bottom portion 3 is about 0.7 mm. In this case, a ratio of the thickness tb to the thickness ta is 14%.

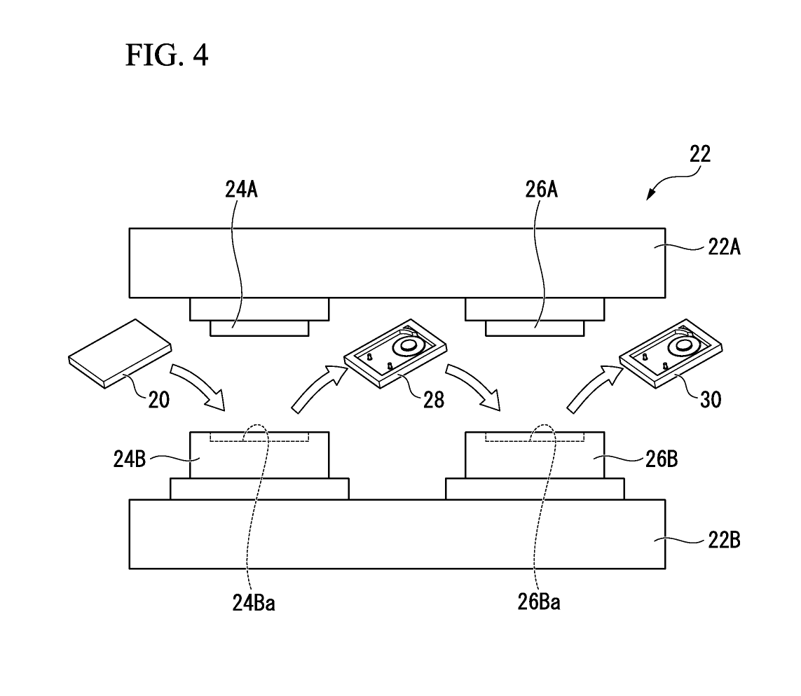

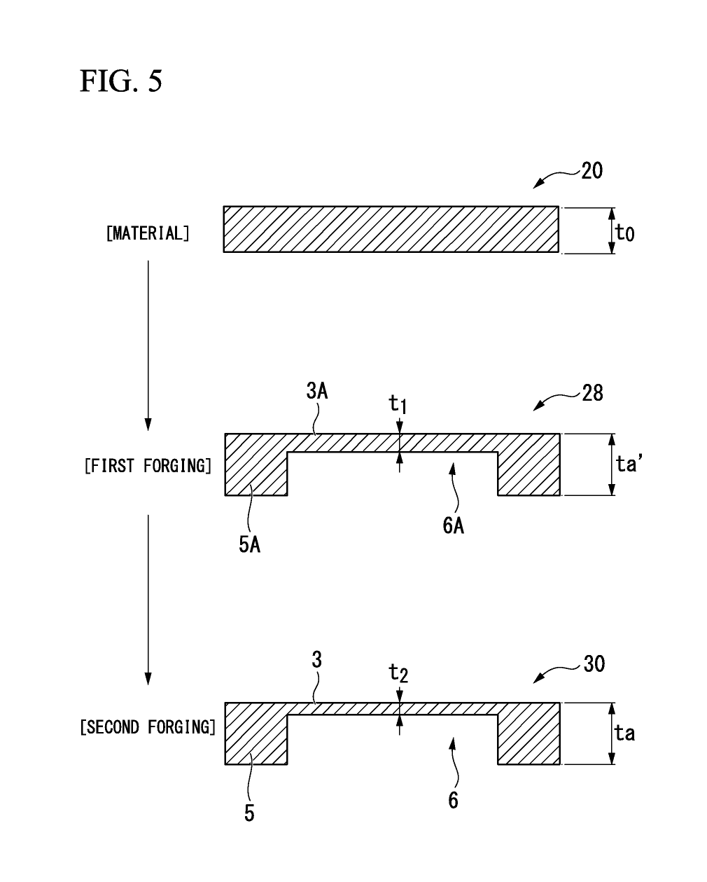

A typical example of an embodiment of the method for manufacturing a semifinished product for a hard disk drive device case body of the present invention will be described with reference to FIGS. 4 and 5.

In FIGS. 4 and 5, a forging material 20 in the embodiment is a plate-like material having a rectangular shape when viewed from a plane view with a predetermined thickness, and is composed of an aluminum alloy having the component composition as described above. The plate surface dimension of the plate-like forging material 20 is defined almost the same as a dimension capable of being charged into a cavity of a lower die in first forging (hot forging) which will be described later, that is, the plane dimension of the outer shape of the semifinished product for a case to be finally obtained (refer to FIGS. 1 to 3). On the other hand, the thickness t₀ of the plate-like material 20 may be the same as or smaller than the total thickness of the semifinished product 30 for a case body to be finally obtained (the thickest portion of the case body semifinished product, that is, corresponding to the thickness ta of the side wall portion 5). However, in the embodiment, as described again later, since the first forging is performed such that the thickness of the side wall portion 5 is increased, the thickness t₀ of the plate-like material 20 is set to be smaller than the thickness ta of the side wall portion 5 of the case body 1. Specifically, the thickness t₀ of the material 20 is set to about 2 mm to 10 mm, and typically, about 3 mm.

Such a plate-like forging material 20 is preheated by a heating furnace (not shown) to a required hot forging temperature and is charged into a cavity 24Ba of a lower die 24B for hot forging in a forging machine 22 and an upper die 24A for hot forging is lowered to perform first forging.

In the embodiment, the forging machine 22 has a configuration in which the upper die 24A for hot forging and the lower die 24B for hot forging constituting a hot forging die, and a upper die 26A for cold forging and a lower die 26B for cold forging constituting a cold forging die are arranged in a parallel manner so that first forging (hot forging) and second forging (cold forging) can be performed in the same forging machine, and the material which undergoes hot forging is removed from the lower die 24B for hot forging and transferred to the position of the lower die 26B for hot forging by a transfer mechanism (not shown) so as to be charged immediately into the lower die 26B for hot forging. The forging machine having such a transfer mechanism is called a forging machine with a transfer. The forging machine 22 with a transfer has a configuration in which the upper die 24A for hot forging and the upper die 26A for cold forging are mounted on the lower side of an upper plate 22A thereof in a parallel manner and the lower die 24B for hot forging and the lower die 26B for cold forging are mounted on the upper side of a lower plate 22B in a parallel manner, and when the upper plate 22A is lifted by a pressure lifting mechanism (not shown), the upper die 24A for hot forging and the upper die 26A for cold forging can be lifted.

A first forging step is basically a step of reducing the thickness of at least a part of the plate-like material 20 by hot forging to form an intermediate concave portion 6A of the semifinished product 30 for a case body to become the housing space 6. Actually, a portion for mounting or holding a hard disk, functional components, or a cover, for example, a portion corresponding to a large diameter boss portion 9, a small diameter boss portion 11, an actuator holding portion 13, or a pin 7 shown in FIGS. 1 to 3 is typically formed in the first forging (hot forging) step, as required.

In the first forging (hot forging) step, the material 20 is charged into the cavity 24Ba of the lower die 24B for hot forging as described above and the upper die 24A for hot forging is lowered to perform hot forging on the material 20 in the cavity 24Ba. Then, the material is formed into an intermediate product 28 having a predetermined intermediate shape and intermediate dimension.

The intermediate product 28 is basically formed to have a plate-like bottom portion 3A to become the bottom portion 3 in the semifinished product 30 for a case body and a side wall portion (outer portion) 5A which stands from the edge portion of the bottom portion 3A to one side with respect to the plate surface of the bottom portion 3A and continues in a rectangular annular shape. The recessed space 6A defined by the bottom portion 3B and the side wall portion 5A is a space to become the housing space 6. Although not shown in FIG. 5, the intermediate product 28 typically has a portion for mounting or holding a hard disk drive, functional components, or a cover, as required.

Here, the shape and the dimension of each portion of the intermediate product 28 are preferably close to the shape and dimension of the semifinished product for a case body to be obtained as described again later.

Specifically, as shown in FIG. 5, for example, when the thickness of the thinnest portion (typically, the bottom portion 3A) in the intermediate product 28 after the first forging step (hot forging) ends is t₁, and the thickness of the thinnest portion (typically, the bottom portion 3) in the semifinished product 30 after the second forging step (cold forging) ends is t₂, a work amount (thickness reduction) in the first forging step (hot forging) is preferably determined such that a thickness reduction Δt₁ (=t₀−t₁) from the thickness t₀ of the material 20 to the thickness t₁ of the thinnest portion of the intermediate product 28 which has been subjected to the first forging step (hot forging) is 80% or more of a total thickness reduction Δt₀ (=t₀−t₂) from the thickness t₀ of the material 20 to the thickness t₂ of the thinnest portion of the semifinished product 30 which has been subjected to the second forging step (cold forging). Further, when it comes to an upsetting rate of the forging (thickness reduction rate from the thickness t₀ of the material 20 to the thickness t₁ of the thinnest portion of the intermediate product which has been subjected to hot forging), the upsetting rate in the first forging step (hot forging) is preferably 60% or more.

In summary,

when the thickness of the material is t₀,

the thickness of the bottom portion 3A of the intermediate concave portion 6A in the intermediate product 28 after the first forging step ends is t₁,

the thickness of the bottom portion 3 of the semifinished product 30 which has been subjected to the second forging step (cold forging) is t₂, and further

Δt₁=t₀−t₁, and

Δt₀=t₀−t₂,

the condition of Δt₁≧0.8×Δt₀ is preferably satisfied and

the condition of Δt₁/t₀≧0.6 is also preferably satisfied.

A specific thickness of the intermediate product 28 which has been subjected to the first forging step (hot forging) is, for example, a thickness t₁ of the thinnest portion (typically, the bottom portion 3A) of about 0.5 mm to 4.0 mm (1 mm as a typical example) and a thickness to of the thickest portion (typically, the side wall portion 5A) of about 4 mm to 25 mm (5 mm as a typical example).

The thickness of the thinnest portion (typically, the side wall portion 5A) is preferably increased from the thickness t₀ of the material by applying back pressure at the hot forging as described again later, and by increasing the thickness in the first forging step in this manner, the thickness of the thickest portion (side wall portion 5A) which has been subjected to the first forging step (hot forging) is preferably set to a thickness ta′ close to the thickness ta of the thickest portion (side wall portion 5) of the of the case body semifinished product 30 which has been subjected to the second forging step (cold forging). Specifically, the thickness ta′ of the thickest portion (side wall portion 5A) of the semifinished product 30 which has been subjected to the first forging step (hot forging) is preferably within a range of 100% to 110% of the thickness ta of the thickest portion (side wall portion 5) of the semifinished product 30 which has been subjected to the second forging step (cold forging).

Further, the temperature of the material at forging of the first forging step (hot forging) is preferably within a range of [solidus temperature of material alloy-100° C.] to [solidus temperature of material alloy-50° C.].

When the temperature of the material at forging in the first forging step (hot forging) is a low temperature lower than [solidus temperature of material alloy-100° C.], the deformation resistance of the material is increased and thus there is a concern of a defect such as underfill being generated particularly in the thin portion and fine shaped portion of the intermediate product which has been subjected to hot forging. Particularly, when a material alloy, such as an Al—Si eutectic alloy or a 6000 series alloy, which facilitates age hardening, is used for the semifinished product which has been subjected to the second forging step (cold forging), at a low temperature in which the temperature of the material is lower than [solidus temperature of material alloy-100° C.] at the first forging, an element contributing to age hardening, for example, Mg or the like cannot be sufficiently solid-solved. As a result, it is difficult to increase the strength of the semifinished product by age hardening.

On the other hand, when the temperature of the material at forging in the first forging step (hot forging) is a high temperature higher than [solidus temperature of material alloy-50° C.], local melting occurs by heat generation in plastic working at the hot forging and thus there is a concern that die seizure may occurs or that the strength may be deteriorated. Particularly, in manufacturing of the semifinished product for a hard disk drive device case body to be an object in the present invention, even when two-stage forging is applied, the thickness of the thinnest portion needs to be significantly reduced to about 1 mm by the first forging and further a portion having a fine shape for mounting each component of the hard disk drive device has to be formed. In such a significantly reduced portion or fine shaped portion, a deformation at the forging is increased and heat generation in working is increased. Thus, when the temperature of the material is originally high, local melting easily occurs at these portions.

For these reasons, the temperature of the material at the forging in the first forging step (hot forging) is preferably adjusted within the above range. In the actual manufacturing step, it is preferable that the hot forging temperature be maintained within the above range by, immediately before the first forging step (hot forging), charging the forging material into the cavity of the hot forging die while heating the material to a temperature within the above range, and preheating or holding the hot forging die to a predetermined temperature, as described again later.

The solidus temperature of the aluminum alloy varies depending on the component composition and an alloy used as an Al—Si eutectic alloy in Example 1 which will be described later, that is, an Al—Si—Cu—Mg-based alloy including Si: 10%, Fe: 0.25%, Cu: 1.0%, Mg: 0.5%, and a balance consisting of Al and unavoidable impurities, has a solidus temperature of 540° C. and thus the temperature of the material at hot forging is preferably within a range 490° C. to 440° C.

In addition, an alloy used as a 6000 series alloy in Example 2, that is, an Al—Si—Cu—Mg-based alloy including Si: 0.6%, Fe: 0.2%, Cu: 0.3%, Mg: 1.0%, and a balance consisting of Al and unavoidable impurities has a solidus temperature of about 580° C. and thus the temperature of the material during hot forging is preferably within a range 530° C. to 480° C.

Further, an alloy used as a 7000 series alloy in Example 4, that is, an Al—Zn—Mg-based alloy including Zn: 6.2%, Mg: 2.2%, Cu: 2.3%, and a balance consisting of Al and unavoidable impurities has a solidus temperature of about 490° C. and thus the temperature of the material at hot forging is preferably within a range 390° C. to 440° C.

An alloy used as a 2000 series alloy in Example 5, that is, an Al—Cu-based alloy including Cu: 4.0%, Si: 0.6%, Mg: 0.6%, Mn: 0.7%, and a balance consisting of Al and unavoidable impurities has a solidus temperature of about 510° C. and thus the temperature of the material at hot forging is preferably within a range 410° C. to 460° C.

An alloy used as a pure aluminum (1000 series) alloy in Example 3 has a solidus temperature of about 640° C. and thus the temperature of the material during hot forging is preferably within a range of 540° C. to 590° C.

After the hot forging by the first forging step, as a transfer step, the intermediate product 28 is removed from the cavity 24Ba of the lower die 24B for hot forging and immediately charged into a cavity 26Ba of the adjacent lower die 26B for cold forging. Next, as the first forging step, the intermediate product 28 is cold-forged by lowering the upper die 26A for cold forging to form a semifinished product 30 for a case body.

Here, the intermediate product 28 which is removed from the cavity 24Ba of the lower die 24B for hot forging still has a high temperature immediately after being removed. However, when the intermediate product is charged into the cavity 26Ba of the lower die 26B for cold forging and cold-forged, heat is taken (dissipated) and rapidly cooled by these cold forging dies (lower die 26B for cold forging and upper die 26A for cold forging) during the time from when the intermediate product is brought into contact with the lower die 26B for cold forging to when the intermediate product is further brought into contact with the upper die 26A for cold forging and cold-forged. That is, heat transfer (cooling) from the intermediate product 28 to the cold forging die occurs mainly during the time from when the intermediate product 28 is charged into the cold forging die and the intermediate product 28 is brought into contact with the surfaces of the lower die 26B for cold forging and the upper die 26A for cold forging to when the intermediate product 28 is subjected to plastic deformation by cold forging until a forged product is discharged from the cold forging die. During the process, the heat of the intermediate product 28 is moved from the surface of the cold forging die to the inside of the die and the intermediate product 28 is rapidly cooled to a temperature of 80° C. or lower.

When an age hardening type Al alloy, such as the above-described Al—Si eutectic alloy represented as an “AHS” alloy or 6000 series alloy, is used as a material, a component element contributing to age hardening can be solid-solved, that is, solutionized by rapid cooling after the hot forging. That is, a so-called die quenching effect can be obtained. Accordingly, in this case, the strength can be increased by natural aging after the second forging. Depending on cases, or the type of alloy, as described later, heat treatment may be performed as an artificial aging treatment.

With respect to the cooling rate when the intermediate product is rapidly cooled by heat extraction effect from the cold forging die after the hot forging, an average cooling rate during the time when the temperature drops from [solidus temperature of material alloy-100° C.] to 80° C. or lower is preferably 50° C./sec or more. In this manner, when an age hardening type Al alloy, such as the above-described Al—Si eutectic alloy represented as an “AHS” alloy or 6000 series alloy, is used, a component element contributing to age hardening can be reliably solid-solved, that is, solutionized by rapid cooling after the hot forging by adjusting the cooling rate. When the average cooling rate during the time when the temperature drops from [solidus temperature of material alloy-100° C.] to 80° C. or lower is less than 50° C./sec, the element contributing to age hardening is precipitated in the cooling process and there is a concern that the strength may not be increased by age hardening after the second forging (cold forging). Further, when precipitates are generated in the cooling process, the deformability of the materiel is reduced, which may disrupt the cold forging in the second forging step. The average cooling rate during the time when the temperature drops from [solidus temperature of material alloy-100° C.] to 80° C. or lower is particularly preferably 90° C./sec or more even within the above range.

Since the Al—Si eutectic alloy in Example 1 which will be described later has a solidus temperature of 540° C. as already described above, in order to obtain the average cooling rate of the above-described rapid cooling process, the alloy is preferably cooled from 440° C. to 80° C. or lower within 8 seconds. In addition, since the 6000 series alloy in Example 2 which will be described later has a solidus temperature of 580° C. as already described above, in order to obtain the average cooling rate of the above-described rapid cooling process, the alloy is preferably cooled from 480° C. to 80° C. or lower within 9 seconds.

Further, in order to reliably obtain the effect of rapid cooling by heat extraction effect from the above-described cold forging die, as described above, cooling means is preferably provided in the cold forging die so that the temperature of the cold forging die is not increased to a high temperature higher than 80° C. by charging of the intermediate product.

In the first forging step (hot forging) before the second forging step (cold forging), as already described above, it is preferable that forging be performed such that a thickness reduction Δt₁ (=t₀−t₁) from the thickness t₀ of the material 20 to the thickness t₁ of the thinnest portion of the intermediate product 28 which has been subjected to the first forging step (hot forging) is 80% or more of a total thickness reduction Δt₀ (=t₀−t₂) from the thickness t₀ of the material 20 to the thickness t₂ of the thinnest portion of the semifinished product 30 which has been subjected to the second forging step (cold forging), the thickness t₀ of the material 20, and thus, in the following second forging step (cold forging), a thickness reduction Δt₂ (=t₀−t₂) is preferably 20% or less of the rest. In this case, when it comes to the upsetting rate of the second forging (thickness reduction rate from the thickness t₁ of the intermediate product 28 to the thickness of the thinnest portion t₂ of the intermediate product which has been subjected to cold forging), the upsetting rate is preferably 20% or less. As specific thickness of the intermediate product 28 which has been subjected to the second forging (cold forging), for example, the thickness t₂ of the thinnest portion (typically, bottom portion 3) is about 0.5 mm to 3 mm (as a typical example, 0.7 mm), and the thickness to of the thickest portion (typically, side wall portion 5) is about 4 mm to 25 mm (as a typical example, 5 mm).

The semifinished product for a case body obtained in the above-described manner is typically subjected to finishing such as machining (cutting or polishing a part of the surface) for finishing a case body product to be finally used for a hard disk drive device case, machining such as punching for mounting each component of the hard disk drive device, and other surface treatment, as required. In addition, finishing may be performed after being subjected to artificial aging treatment or natural aging by being left at room temperature depending on the type of material alloy.

### [Overall Manufacturing Process]

Next, a preferable embodiment and preferable conditions of the overall process from a process of manufacturing a forging material to a process of forming a semifinished product for a case body and further finishing the material into a disk drive device case body as a final product by machining through the first forging step, the transfer step, and the second forging step, will be described.

### <Material Manufacturing Step>

A method for manufacturing a material is not particularly limited and a continuous casting method is preferably applied. That is, a cast slab is formed from a molten aluminum alloy in which a predetermined component composition is adjusted by so-called continuous casting methods including a general continuous casting method such as a hot-top continuous casting method, or a continuous casting and rolling (thin plate continuous casting), and further, a semi-continuous casting method. Here, as a specific embodiment of the continuous casting, either of horizontal continuous casting and vertical type continuous casting may be used and also a gas pressurization continuous casting method may be applied. The shape of the cast slab obtained by the continuous casting is not particularly limited and any of a round rod-like billet, a rectangular rod-like billet, or a plate-like billet may be used. When such a continuous casting method is applied, not only can the productivity be increased, but also a cast slab having a fine casting structure and a small amount of precipitates can be obtained, for example, when the above-described Al—Si eutectic alloy is used.

The cast slab obtained in this manner is typically subjected to homogenization treatment as required and further subjected to machining. The temperature (atmosphere temperature) of the homogenization treatment is preferably set to 500° C.±30° C. When the temperature of the homogenization treatment is within this range, the effect of achieving homogeneous segregation at casting can be obtained and coarsening of a transition metal element functioning as a nucleus for recrystallization does not occur. Thus, the temperature range is preferable from the viewpoint of preventing coarse recrystallization. When the temperature of the homogenization treatment is lower than the above range, the effect of achieving homogeneous segregation at casting is not easily obtained. On the other hand, when the temperature is higher than the above range, the precipitation of the transition metal element is coarsened, and the effect of preventing coarse recrystallization is reduced. Particularly, in the case of an aluminum alloy to which Fe and Mn are added, in order to obtain a higher effect, this range is preferable. The holding time at the temperature of the homogenization treatment within the above range is preferably set to 5 hours to 20 hours.

When a pure aluminum alloy is used as material, the homogenization treatment of the cast slab can be omitted.

Thereafter, as required, material working treatment for working the material into a material shape (for example, the shape of the plate surface is a rectangular plate-like shape) suitable for the first forging step (hot forging) and a dimension is performed. As the material working treatment, shear cutting, extrusion, or upsetting is preferably applied according to the shape of the case piece. Further, two or more types of working may be combined. For example, when the continuous cast slab is a round rod-like billet, the round rod-like billet may be subjected to shear cutting to be shortened and worked into a plate-like shape having a required dimension by upsetting or extrusion to form a forging material. In addition, when the continuous cast slab has a thin plate-like shape, the cast slab can be subjected to only shear cutting to form a forging material.

When upsetting or extrusion is applied to the cast slab as working means for working the cast slab into a plate-like forging material having a required dimension, the upsetting or extrusion is preferably performed in a hot or warm state. In this case, hot forging as the first forging step may be performed immediately after upsetting or extrusion may be performed after forging preheating as described below.

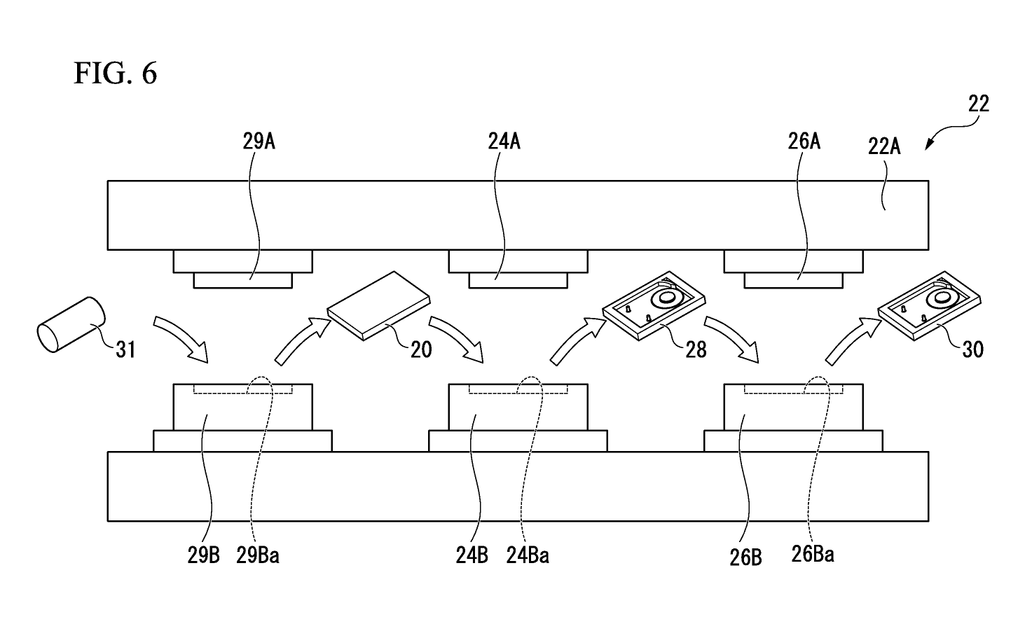

Here, an example of the forging machine 22, when, for example, the round rod-like cast slab is used and cut into a short round rod-like slab having a predetermined length, the short round rod-like slab is subjected to upsetting and then hot forging as the first forging step, the transfer step, and the cold forging as the second forging step, is shown in FIG. 6. In FIG. 6, the forging machine 22 with a transfer has a configuration in which an upper die 29A for upsetting and a lower die 29B for upsetting constituting an upsetting die, the upper die 24A for hot forging and the lower die 24B for hot forging constituting the hot forging, and the upper die 26A for cold forging and the lower die 26B for cold forging constituting the cold forging die are arranged in a parallel manner so that the upsetting, the first forging (hot forging), and the second forging (cold forging) can be performed in the same forging machine. That is, the upper die 29A for upsetting, the upper die 24A for hot forging, and the upper die 26A for cold forging are mounted on the lower side of the upper plate 22A of the forging machine 22 in a parallel manner and the lower die 29B for upsetting, the lower die 24B for hot forging, and the lower die 26B for cold forging are mounted on the upper side of the lower plate 22B in a parallel manner, and when the upper plate 22A is lifted by a pressure lifting mechanism (not shown), the upper die 29A for upsetting, the upper die 24A for hot forging, and the upper die 26A for cold forging can be lifted.

In this case, first, the above-described short round rod-like slab 31 which is preheated to a predetermined temperature is charged into a cavity 29Ba of the lower die 29B for upsetting and the short round rod-like slab 31 is crushed to be flat. The obtained plate-like forging material 20 is charged into the lower die 24B for hot forging as already described above and the first forging step (hot forging) is performed and further the intermediate product 28 which has been subjected to hot forging is removed from the lower die 24B for hot forging and transferred to the position of the lower die 26B for cold forging. The intermediate product is charged into the lower die 26B for cold forging and the first forging step (hot forging) can be performed.

### <Forging Preheating Step>

The forging material is subjected to preheating for heating the material to the temperature of the material at the forging in the first forging step (hot forging). As already described above, the temperature of the material at the forging in the first forging step (hot forging) is preferably a temperature within the range of [solidus temperature of material alloy−100° C.] to [solidus temperature of material alloy−50° C.], and thus, the forging preheating temperature is also preferably a temperature within the above range or a temperature slightly higher than the above range. The point is that the preheating time may be set such that the material is heated until the temperature inside the material is uniformly heated to a temperature within the above range, and a time of about 10 minutes to 30 minutes is typically sufficient.

When the preheated forging material is charged into the cavity of the lower die 24B of the hot forging die, the time from immediately after the preheating until the discharging is preferably controlled to be short, such as, for example, 20 seconds or less so as not to reduce the temperature of the material during the charging. In addition, the semifinished product for a case body as an object in the present invention has a thick portion and also a thin portion and a fine shaped portion, and thus, it is preferable that a high preheat set temperature be set by predicting a decrease in the temperature of the material to maintain a balance between the fluidity of the material to the thin portion and the fine shaped portion at the hot forging and the back pressure mainly for forming the thick portion or controls of appropriately providing the holding time be performed to obtain a uniform temperature distribution in the material.

### <First Forging Step (Hot Forging)>

The preheated forging material is charged into, for example, the cavity 24Ba of the lower die 24B for hot forging in the forging machine 22 shown in FIG. 4 and the lower die 24B for hot forging is lowered to perform hot forging on the material.

The temperature of the material at the forging in the first forging step (hot forging) is preferably a temperature within the range of [solidus temperature of material alloy−100° C.] to [solidus temperature of material alloy−50° C.], as already described above.

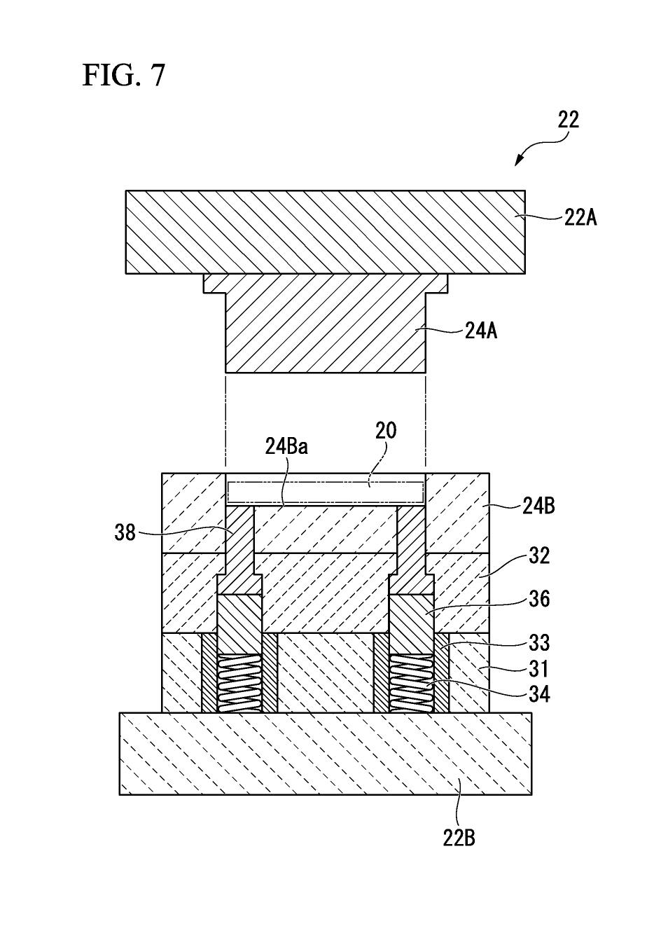

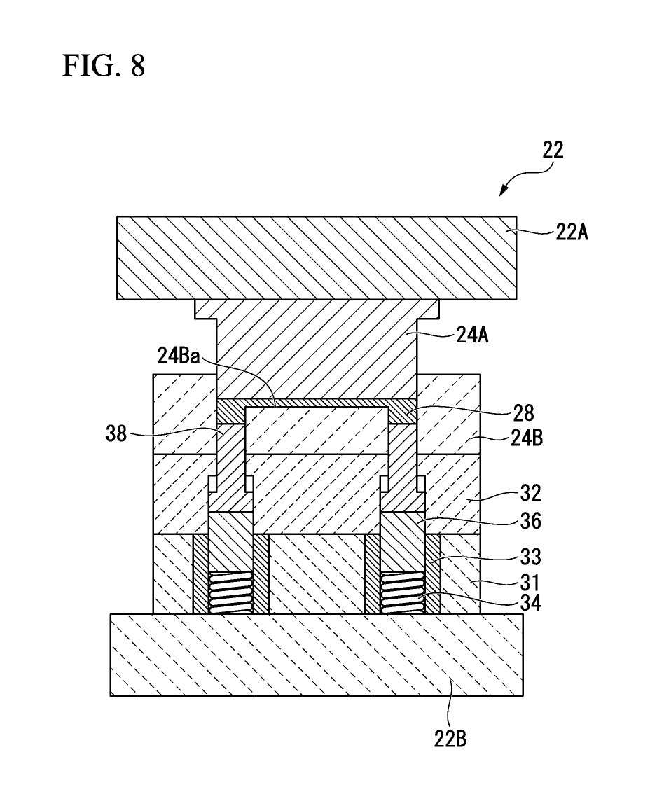

Further, the first forging step is preferably hot forging performed in a state in which back pressure is partially applied. That is, forging that is performed such that while the back pressure is applied to a portion to become a thick portion in the semifinished product for a case body (for example, a portion corresponding to the side wall portion 5 or pin 7 in FIGS. 1 to 3), the back pressure is not applied to a portion to become a thin portion (for example, bottom portion 3 in FIGS. 1 to 3), a so-called partial back pressure applying forging method is preferably applied. An example of a hot forging die for forming a case body material by forging by the partial back pressure applying forging method is shown in FIGS. 7 and 8. In FIGS. 7 and 8, the vertical cross-sectional view of the hot forging die is schematically shown at a position corresponding to a vertical cross-sectional view taken along line II-II of FIG. 1 (refer to FIG. 3) in the case body. Further, in FIGS. 7 and 8, the forging material 20 for a case body is formed by forging in a state in which the up and down sides of FIGS. 1 to 3 are inverted, that is, formed by forging in a state in which the open side of the intermediate product for a case body is directed downward.

In FIGS. 7 and 8, the upper die 24A for hot forging is mounted downward on the lower side of the upper plate 22A of the forging machine 22. On the other hand, the lower die 24B for hot forging is mounted on the lower plate 22B of the forging machine 22 from the lower side through a holding plate 31 and a pressure receiving plate 32. The cavity 24Ba opened upward is formed in the lower die 24B for hot forging. The bottom surface of the cavity 24Ba corresponds to the inner surface of the bottom portion of a case body. An upper end surface of a back pressure applying member 38 which will be described later is exposed in the peripheral portion of the bottom surface of the cavity 24Ba.

Here, the holding plate 31 holds a hollow cylindrical pneumatic cylinder 33 which holds air pressure for back pressure as a back pressure cushion. A spring member 34 for absorbing shock is housed on the inner lower side of the pneumatic cylinder 33 and an intermediate lifting member 36 that can be lifted and lowered while sliding vertically is arranged on the upper side of the spring member 34 so that the upper end thereof reaches the inside of the pressure receiving plate 32. Further, the back pressure applying member 38 is arranged on the intermediate lifting member 36. The back pressure applying member 38 is a member that can be lifted or lowered with respect to the lower die 24B for hot forging and can be referred to as a movable die for forming the peripheral portion of the forging material 20 (a portion corresponding to the side wall portion of the case body). The upper surface of the back pressure applying member 38 is positioned so as to be substantially leveled with the bottom surface of the cavity 24Ba when the die is opened (in a state in which the upper die 24A for hot forging is positioned at the top dead center: refer to FIG. 7).

When the forging material 20 is forged by using such a hot forging die, as shown in FIG. 7, in a state in which the die is opened, the plate-like forging material 20 is charged into the cavity 24Ba of the lower die 24B for hot forging and the upper die 24A for hot forging is lowered by lowering the upper plate 22A so as to apply a forging load on the material 20 in the cavity 24Ba by the lower surface of the upper die 24A for hot forging. At this time, the thickness of a portion in contact with the bottom surface of the cavity 24Ba (corresponding to the inner surface of the bottom portion of the case body) is reduced by the forging load as it is and thus a thin portion (bottom portion) is formed. On the other hand, when the back pressure which is applied to the peripheral portion of the material 20 by the pneumatic cylinder 33 through the intermediate lifting member 36 and the back pressure applying member 38 is set to be slightly smaller than the pressure resulting from the forging load, the back pressure applying member 38 which is a movable die is lowered and a portion of the material (peripheral portion of the plate-like material 20) is correspondingly formed to be thick. In the example shown in the drawing, the thickness of the peripheral portion of the plate-like material is increased. In this manner, the intermediate product 28 in which a thin portion and a thick portion are complicated and the difference between the thin portion and the thick portion is small can be easily forged and formed by hot forging while the back pressure is partially applied. In addition, a portion corresponding to the pin 7 in FIGS. 1 to 3 is also a thick portion and thus, although not shown in FIGS. 7 and 8, the back pressure is preferably applied to the portion corresponding to the pin 7.

Although not shown in FIGS. 7 and 8, it is preferable that heating means such as an electric heater be provided to the lower die 24B of the hot forging die or the lower die 24B and the upper die 24A and these dies be preheated or heated and held to about 200° C. to 300° C. so that an appropriate temperature of the material is held at the hot forging.

### <Transfer Step and Second Forging Step (Cold Forging)>

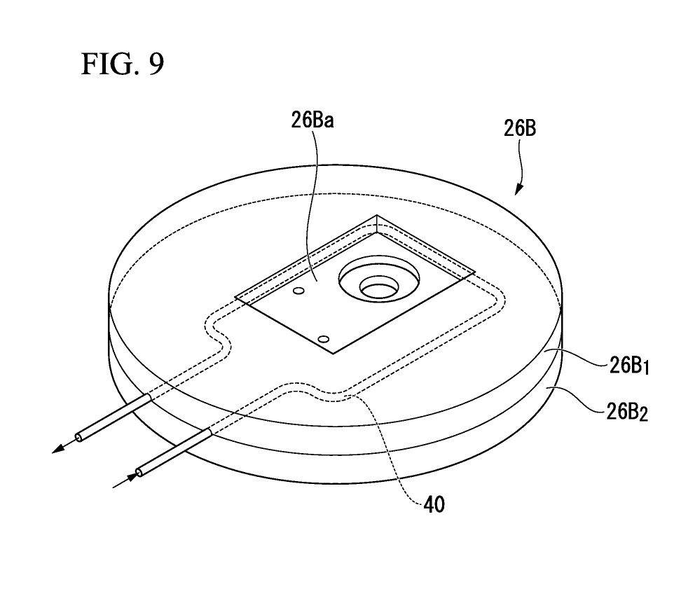

After the intermediate product obtained by the above-described first forging step (hot forging) is removed from the cavity of the lower die for hot forging, the intermediate product is immediately transferred to the position of the lower die for cold forging (transfer step), charged into the cavity of the lower die for cold forging, and provided in the second forging step. At this time, when the intermediate product is brought into contact with the cold forging die (lower die and upper die additionally) as already described above, the heat of the intermediate product is taken by the die and the intermediate product is rapidly cooled. The cooling rate at this time is preferably adjusted to have an average cooling rate of 50° C./sec or more during the time when the temperature drops from [solidus temperature of material alloy−100° C.] to 80° C. or lower as already described above. For that, the time from when the intermediate product which has been subjected to hot forging is removed from the hot forging die to when the intermediate product is charged into the cold forging die and cold forging starts (specifically, time from when the intermediate product is brought into the lower die for cold forging to when the upper die is further brought into contact with the intermediate product) is preferably reduced as much as possible. Specifically, the time from when the intermediate product is removed from the hot forging die to when the intermediate product is charged into the cold forging die and cold forging starts is preferably set to be less than or equal to 10 seconds. At the same time, cooling means is preferably provided in the cold forging die so that the temperature of the cold forging die is not increased by the intermediate product having a high temperature immediately after the hot forging. In this manner, an example of the lower die 26B for cold forging in which the cooling means is provided is shown in FIG. 9.

In FIG. 9, the lower die 26B for cold forging is constituted by upper and lower die members 26B₁ and 26B₂. A cooling pipe 40 is arranged between these die members 26B₁ and 26B₂ so as to surround the cavity 26Ba as the cooling means. In the cooling pipe 40, a cooling catalyst such as cooling water having a water temperature of, for example, about 50° C. or lower, and preferably 40° C. or lower flows so that the temperature of lower die 26B for cold forging, particularly, the temperature of the inner surface of the cavity 26Ba, can be held at a low temperature.

### <Aging Treatment>

In the case of using an alloy such as an Al—Si eutectic alloy or a 6000 series alloy as the aluminum alloy material, which facilitates age hardening, when the semifinished product which has been subjected to cold forging in the second forging step is left at room temperature for 24 hours or more as it is, the strength can be increased by natural aging (room temperature aging). However, in order to achieve higher strength, artificial aging treatment may be performed. The optimum condition for artificial aging varies depending on the component composition of the alloy, and typically, heating may be performed at about 170° C. to 220° C. for about 1 hour to 8 hours.

### <Finishing>

In order to finally finish the semifinished product into a case body product used for a hard disk drive device case, the semifinished product for a case body obtained in the above-described manner is typically subjected to finishing such as machining such as cutting or polishing of a part of the surface, or punching for mounting each component of a hard disk drive device, and other surface treatment as finishing. Here, in the case product in a final use state, the outer portion which does not require machining accuracy typically remains as a forged surface which has been subjected to cold forging as it is and thus a portion to be subjected to cutting or polishing is mainly a mounting or joining portion of each component of a hard disk drive device, and the peripheral portion thereof.

Examples of the present invention will be described below. The following examples are to clarify the action and the effect of the present invention and the conditions described in the examples are not intended to limit the technical scope of the present invention.

### EXAMPLES

### Example 1

Example 1 is an example in which a case body semifinished product for a hard disk drive device case body having a thin box-like shape as schematically shown in FIGS. 1 to 3 is manufactured by forging the material by the forging machine shown in FIG. 6 using an Al—Si eutectic alloy as a forming material alloy.

As the Al—Si eutectic alloy, an Al—Si—Cu—Mg-based alloy including Si: 10%, Fe: 0.25%, Cu: 1.0%, Mg: 0.5%, and a balance consisting of Al and unavoidable impurities was used. In addition, a target dimension of a semifinished product for a case body to be finally obtained had a 70 mm×100 mm rectangular shape, when viewed from a plane view, and the thickness to of the thickest portion (side wall portion 5) was 10 mm and the thickness tb of the thinnest portion (bottom portion 3) was 2 mm.

A molten Al—Si eutectic alloy having the above-described component composition was prepared by a typical method and a round rod-like cast slab having an outer diameter of 28 mm was obtained by a gas pressurization hot-top continuous casting method. The cast slab was subjected to homogenization treatment at 490° C. for 10 hours and then was cut to have a length of 95 mm while being subjected to surface cutting. The cast slab was preheated to 480° C. by a heating furnace and was upset into a plate-like material by the upper setting die of the forging machine 22 with a transfer shown in FIG. 6. The dimension of the obtained plate-like material was 68 mm×98 mm when viewed from a plane view and the thickness t₀ was 5.5 mm. The plate-like material after the upsetting was immediately charged into the cavity of the hot forging die schematically shown in FIGS. 7 and 8, and hot forging (first forging) was performed so as to obtain an intermediate product. The temperature of the material when the material was charged into the cavity of the hot forging die was about 460° C. In addition, in the hot forging, the die was preheated to 380° C. in advance. Further, a portion corresponding to the side wall portion or a portion corresponding to the pin in the case body was forged by applying a back pressure of 6 kgf/mm² with a total forging load of 250 t at a forging rate (upper die lowering rate) of 90 mm/sec.

The dimension of the obtained intermediate product was a 70 mm×100 mm rectangular shape when viewed from a plane view, and the thickness ta′ of the thickest portion (side wall portion 5) was 9.8 mm and the thickness t₁ of the thinnest portion (bottom portion 3) was 2.5 mm with respect to the thickness.

Next, the intermediate product removed from the hot forging die was immediately charged into the cavity of the cold forging die and the second forging (cold forging) was performed. Here, the cold forging die was cooled and held to 50° C. or lower by the cooling means as shown in FIG. 9. At this time, the time from when the intermediate product was removed from the hot forging die to when the intermediate product was charged into the cavity of the cold forging die and further subjected to cold forging was about 2 seconds and the average cooling rate during the time from when the temperature of the intermediate product (about 440° C.) at the time of being removed from the hot forging die to when the intermediate product was brought into contact with the cold forging die and cooled to 80° C. or lower was 180° C./sec. In addition, in the second forging (cold forging), forging was performed with a forging load of 50 t at a forging rate (upper die lowering rate) of 90 mm/sec.

The dimension of the obtained semifinished product was 70 mm×100 mm when viewed from a plane view, and the thickness ta of the thickest portion (side wall portion 5) was 10 mm and the thickness t₂ of the thinnest portion (bottom portion 3) was 2 mm with respect to the thickness.

The obtained semifinished product was left at room temperature for 24 hours and subjected to natural aging.

When the strength of the obtained semifinished product alter natural aging was investigated, the strength of the side wall portion (thickest portion) of the semifinished product for a case body was 284 MPa, and the strength of the bottom portion was 290 MPa. Further, when the hardness of each portion was investigated as an index of the rigidity of the case body, the hardness of the side wall portion (thickest portion) was Hv 91, and the hardness of the bottom portion was Hv 92. As clearly seen from these measurement values, the product had sufficient hardness and rigidity as a hard disk drive device case body.

The strength of the side wall portion (thickest portion) of the semifinished product for a case body immediately after being removed from the cold forging die was 260 MPa, and the hardness was Hv 82. In addition, the strength of the bottom portion was 260 MPa and the hardness was Hv 82. Thus, it was clear that age hardening was facilitated by natural aging in which the product was left for 24 hours as described above.

When the semifinished product for a case body removed from the cold forging die was subjected to artificial aging at 200° C. for 360 minutes, the strength of the side wall portion (thickest portion) of the semifinished product for a case body was 305 MPa and the hardness was Hv 99. Further, the strength of the bottom portion was 310 MPa and the hardness was Hv 100.

For reference, in the above Example 1, a test was conducted under the conditions in which the time from when the intermediate product was removed from the hot forging die cold forging die to when the intermediate product was charged into the cavity and further subjected to cold forging was changed to about 60 seconds and the average cooling rate during the time when the temperature dropped from the temperature of the intermediate product (about 440° C.) at the time of being removed from the hot forging die to when the intermediate product was brought into contact with the cold forging die and cooled to 80° C. or lower was about 6° C./sec. In this case, the strength of the side wall portion (thickest portion) of the semifinished product for a case body immediately after being removed from the cold forging die was 260 MPa and the hardness was Hv 82. Further, the strength of the bottom portion was 260 MPa and the hardness was Hv 82. The strength of the side wall portion (thickest portion) of the semifinished product for a case body immediately after being removed from the cold forging die and then left at room temperature for 24 hours was 266 MPa and the hardness was Hv 83. Further, the strength of the bottom portion was 268 MPa and the hardness was Hv 84. Accordingly, in this case, it was proved that sufficient age hardening was not facilitated by natural aging in which the product was left for 24 hours as described above. When the semifinished product for a case body removed from the cold forging die was subjected to artificial aging at 200° C. for 360 minutes just in case, the strength of the side wall portion (thickest portion) of the semifinished product for a case body was 284 MPa and the hardness was Hv 91. Further, the strength of the bottom portion was 286 MPa and the hardness was Hv 91. Thus, it was found that even when artificial aging was performed, the strength of the bottom portion was slightly increased.

### Example 2

Example 2 is an example in which a semifinished product for a hard disk drive device case body having a thin box-like shape as schematically shown in FIGS. 1 to 3 is manufactured by forging the material by the forging machine with a transfer shown in FIG. 4 using a 6000 series alloy as a forming material alloy.

Here, as the 6000 series alloy, an alloy including Si: 0.6%, Cu: 0.3%, Mg: 1.0%, Cr: 0.15%, Mn: 0.15%, Fe: 0.2%, and a balance consisting of Al and unavoidable impurities was used. In addition, a target dimension of a semifinished product for a case body to be finally obtained was a 70 mm×100 mm rectangular shape when viewed from a plane view, and the thickness to of the thickest portion (side wall portion 5) was 10 mm and the thickness tb of the thinnest portion (bottom portion 3) was 2 mm.

The 6000 series alloy having the above-described component composition was melted by a typical method to obtain a plate-like cast slab having a thickness of 10 mm by a continuous casting rolling method (thin plate continuous casting method). The plate-like cast slab was subjected to homogenization treatment at 540° C. for 10 hours and then was cut into a rectangular shape having a plane dimension of 68 mm×98 mm (with a thickness of 5.5 mm) by shear cutting while being subjected to surface cutting so as to form a plate-like forging material. The plate-like forging material was preheated to 530° C. by a heating furnace and immediately charged into the cavity of the hot forging die schematically shown in FIGS. 7 and 8, and hot forging (first forging) was performed to obtain an intermediate product. The temperature of the material when the material was charged into the cavity of the hot forging die was about 520° C. In the hot forging, the die was preheated to 480° C. in advance. In addition, a portion corresponding to the side wall portion or a portion corresponding to the pin in the case body was forged by applying a back pressure of 5 kgf/mm² with a total forging load of 220 t at a forging rate (upper die lowering rate) of 90 mm/sec.

The dimension of the obtained intermediate product was a 70 mm×100 mm rectangular shape when viewed from a plane view, and the thickness ta′ of the thickest portion (side wall portion 5) was 9.8 mm and the thickness t₁ of the thinnest portion (bottom surface 3) was 2.5 mm with respect to the thickness.

Next, the intermediate product removed from the hot forging die was immediately charged into the cavity of the cold forging die and the second forging (cold forging) was performed. Here, the cold forging die was cooled and held to 50° C. or lower by the cooling means as shown in FIG. 9. At this time, the time from when the intermediate product was removed from the hot forging die to when the intermediate product was charged into the cavity of the cold forging die and further subjected to cold forging was about 2 seconds, and the average cooling rate during the time when the temperature was cooled from the temperature of the intermediate product (about 510° C.) at the time of being removed from the hot forging die to 80° C. or lower as the product was brought into contact with the cold forging die was 215° C./sec. In addition, in the second forging (cold forging), forging was performed with a forging load of 40 t at a forging rate (upper die lowering rate) of 90 mm/sec.

The dimension of the obtained semifinished product was 70 mm×100 mm when viewed from a plane view, and the thickness ta of the thickest portion (side wall portion 5) was 10 mm and the thickness t₂ of the thinnest portion (bottom portion 3) was 2 mm.

The obtained semifinished product was left at room temperature for 24 hours to cause natural aging.

When the strength of the obtained semifinished product after natural aging was investigated, the strength of the side wall portion (thickest portion) of the semifinished product for a case body was 190 MPa, and the strength of the bottom portion was 200 MPa. Further, when the hardness of each portion was investigated as an index of the rigidity of the case body, the hardness of the side wall portion (thickest portion) was Hv 64, and the hardness of the bottom portion was Hv 66. As clearly seen from these measurement values, the product had sufficient hardness and rigidity as a hard disk drive device case body.

The strength of the side wall portion (thickest portion) of the semifinished product for a case body immediately after being removed from the cold forging die was 170 MPa, and the hardness was Hv 58. In addition, the strength of the bottom portion was 170 MPa and the hardness was Hv 58. Thus, it was clear that age hardening was facilitated by natural aging in which the product was left for 24 hours as described above. When the semifinished product for a case body removed from the cold forging die was subjected to artificial aging at 180° C. for 360 minutes just in case, the strength of the side wall portion (thickest portion) of the semifinished product for a case body was 240 MPa and the hardness was Hv 74. Further, the strength of the bottom portion was 250 MPa and the hardness was Hv 76.

### Example 3

Example 3 is an example in which a semifinished product for a hard disk drive device case body having a thin box-like shape as schematically shown in FIGS. 1 to 3 is manufactured by forging the material by the forging machine with a transfer shown in FIG. 4 using a pure aluminum alloy (1000 series alloy) as a forming material alloy.

As the pure aluminum alloy, an alloy including Si: 0.3%, Fe: 0.3%, Cu: 0.1%, and a balance consisting of Al and unavoidable impurities was used. Further, a target dimension of a case body to be finally obtained was the same as in Example 2.

A semifinished product for a hard disk drive device case body was manufactured in Example 3 in the same manner as in Example 2 except that homogenization treatment after continuous casting was omitted, and further surface cutting after homogenization treatment was omitted.

When the strength of the obtained semifinished product was investigated, the strength of the side wall portion (thickest portion) of the semifinished product for a case body was 100 MPa, and the strength of the bottom portion was 105 MPa. Further, when the hardness of each portion was investigated as an index of the rigidity of the case body, the hardness of the side wall portion (thickest portion) was Hv 28, and the hardness of the bottom portion was Hv 29. Although these measurement values are lower than the values in Examples 1 and 2, the product can be used as a case body of a hard disk drive device depending on the application of a hard disk drive device (type of electronic components to be incorporated).

### Example 4

Example 4 is an example in which a semifinished product for a hard disk drive device case body having a thin box-like shape as schematically shown in FIGS. 1 to 3 is manufactured by forging the material by the forging machine with a transfer shown in FIG. 4 using an Al—Zn—Mg-based alloy (7000 series alloy) as a forming material alloy.

As the 7000 series alloy, an alloy including Zn: 6.2%, Mg: 2.2%, Cu: 2.3%, and a balance consisting of Al and unavoidable impurities was used. In addition, a target dimension of a semifinished product for a case body to be finally obtained was the same as in Example 2.

A semifinished product for a hard disk drive device case body was manufactured in Example 4 in the same manner as in Example 2 except that the temperature of the forging material was changed to 415° C., and the condition for artificial aging was changed.

When the strength of the obtained semifinished product after natural aging was investigated, the strength of the side wall portion (thickest portion) of the semifinished product for a case body was 350 MPa, and the strength of the bottom portion was 380 MPa. Further, when the hardness of each portion was investigated as an index of the rigidity of the case body, the hardness of the side wall portion (thickest portion) was Hv 120, and the hardness of the bottom portion was Hv 124. As clearly seen from these measurement values, the product had sufficient strength and rigidity as a hard disk drive device case body.

The strength of the side wall portion (thickest portion) of the semifinished product for a case body immediately after being removed from the cold forging die was 280 MPa and the hardness was Hv 92. Further, the strength of the bottom portion was 280 MP and the hardness was Hv 92. Accordingly, in this case, it was clear that sufficient age hardening was facilitated by natural aging in which the product was left for 24 hours as described above. When the semifinished product for a case body removed from the cold forging die was subjected to artificial aging at 170° C. for 360 minutes just in case, the strength of the side wall portion (thickest portion) of the semifinished product for a case body was 420 MPa and the hardness was Hv 138. Further, the strength of the bottom portion was 440 MPa and the hardness was Hv 142.

### Example 5

Example 5 is an example in which a semifinished product for a hard disk drive device case body having a thin box-like shape as schematically shown in FIGS. 1 to 3 is manufactured by forging the material by the forging machine with a transfer shown in FIG. 4 using an Al—Cu-based alloy (2000 series alloy) as a forming material alloy.

As the 2000 series alloy, an alloy including Cu: 4.0%, Si: 0.6%, Mg: 0.6%, Mn: 0.7%, and a balance consisting of Al and unavoidable impurities was used. A target dimension of a case body to be finally obtained was the same as in Example 2.

A semifinished product for a hard disk drive device case body was manufactured in Example 5 in the same manner as in Example 2 except that the temperature of the forging material was changed to 435° C.

When the strength of the obtained semifinished product after natural aging was investigated, the strength of the side wall portion (thickest portion) of the semifinished product for a case body was 400 MPa, and the strength of the bottom portion was 410 MPa. Further, when the hardness of each portion was investigated as an index of the rigidity of the case body, the hardness of the side wall portion (thickest portion) was Hv 132, and the hardness of the bottom portion was Hv 136. As clearly seen from these measurement values, the product had sufficient strength and rigidity as a hard disk drive device case body.

The strength of the side wall portion (thickest portion) of the semifinished product for a case body immediately after being removed from the cold forging die was 300 MPa and the hardness was Hv 102. Further, the strength of the bottom portion was 300 MPa and the hardness was Hv 102. Accordingly, in this case, it was clear that sufficient age hardening was facilitated by natural aging in which the product was left for 24 hours as described above. When the semifinished product for a case body removed from the cold forging die was subjected to artificial aging at 180° C. for 360 minutes just in case, the strength of the side wall portion (thickest portion) of the semifinished product for a case body was 430 MPa and the hardness was Hv 139. Further, the strength of the bottom portion was 440 MPa and the hardness was Hv 142.

### Comparative Example 1

Comparative Example 1 is an example in which a semifinished product for a case body is manufactured by a die casting method according to the related art.

As an aluminum alloy of a material, ADC 12 according to JIS standards was used, the molten die-casting alloy of 720° C. was injected into a die for die-casting a case body semifinished product, and a pressure of 90 MPa was applied to manufacture a case body semifinished product. A target shape and dimension of the semifinished product is the same as in Example 1.

In the case of Comparative Example 1, the molten alloy did not extend to the thin portion, which caused a cold shut defect to block the through hole. Thus, the airtightness of the case was not able to be held.

### Comparative Example 2

Comparative Example 2 is an example in which when a semifinished product for a case body is manufactured by forging, the semifinished product for a case body was finished by performing hot forging one time.

As the material alloy, an Al—Si eutectic alloy was used as in Example 1 and the same process as in Example 1 was performed until a plate-like material having a plane dimension of 68 mm×98 mm and a thickness t₀ of 5.5 mm was obtained by upsetting. The material was finished by performing hot forging one time so that the semifinished product for a case body had the same dimension and shape as in Example 1. The condition for hot forging was the same as the condition for hot forging as the first forging in Example 1.

In the case of Comparative Example 2, in the hot forging, even when a formation load was increased, the thin portion was not able to be formed until a desired thickness was obtained and the seizure of the boss portion and underfill were caused. As a result, a product having a predetermined dimension was not able to be obtained.

### REFERENCE SIGNS LIST

1: CASE BODY
3: BOTTOM PORTION
5: SIDE WALL PORTION (OUTER PORTION)
6: HOUSING SPACE
20: FORGING MATERIAL
22: FORGING MACHINE
28: INTERMEDIATE PRODUCT
30: SEMIFINISHED PRODUCT FOR CASE BODY

1. A method for manufacturing an aluminum alloy semifinished product for a hard disk drive device case body having a box-like shape with one open side, the method comprising:
a first forging step of die-forging a forging material composed of an aluminum alloy to an intermediate product by hot forging using a hot forging die;
a transfer step of removing the intermediate product from the hot forging die after the first forging step ends and transferring the intermediate product to a position of a cold forging die to be charged into the cold forging die; and
a second forging step of die-forging the intermediate product into a shape of a semifinished product for a hard disk drive device case body by cold forging,
wherein while the intermediate product is charged into the cold forging die and cold-forged from the transfer step to the second forging step, the intermediate product is rapidly cooled to a cold forging temperature by heat extraction effect from the cold forging die.

2. The method for manufacturing an aluminum alloy semifinished product for a hard disk drive device case body according to claim 1,
wherein when a solidus temperature of the aluminum alloy as the forging material is T° C., the hot forging in the first forging step is performed at a temperature within a range of [T−100]° C. to [T−50° C.] and the cold forging in the second forging step is performed at a temperature of 80° C. or lower, and an average cooling rate from [T−100]° C. to 80° C. or lower in a cooling process from the transfer step to the second forging step after the first forging step ends is 50° C./sec or more.

3. The method for manufacturing an aluminum alloy semifinished product for a hard disk drive device case body according to claim 1,
wherein the cold forging die is cooled to 80° C. or lower in at least in the transfer step and the second forging step.

4. The method for manufacturing an aluminum alloy semifinished product for a hard disk drive device case body according to claim 1,
wherein the semifinished product for a case body to be manufactured has a thin plate-like flat bottom portion and a side wall portion which stands from an edge portion of the bottom portion to one side with respect to the plate surface of the bottom portion, and a recessed space defined by the bottom portion and the side wall portion is a housing space for housing a hard disk and functional components of a hard disk drive device,
the thickness of at least a part of the plate-like material is reduced in the first forging step to form an intermediate concave portion to become the housing space, and
the thickness of the bottom surface of the intermediate concave portion is further reduced in the second forging step to form the housing space.

5. The method for manufacturing an aluminum alloy semifinished product for a hard disk drive device case body according to claim 4,
wherein when the thickness dimension of the semifinished product to be manufactured in a direction orthogonal to the plate surface of the bottom portion thereof is t₂ and the dimension of the side wall portion in the same direction is ta, the condition of t₂≦0.3×ta is satisfied.

6. The method for manufacturing an aluminum alloy semifinished product for a hard disk drive device case body according to claim 5,
wherein when the thickness of the material is t₀,
the thickness of the bottom portion of the intermediate concave portion in the intermediate product after the first forging step ends is t₁,
the thickness of the bottom portion of the semifinished product which has been subjected to the second forging step (cold forging) is t₂, and further
Δt₁=t₀−t₁, and
Δt₀=t₀−t₂,
the condition of Δt₁≧0.8×Δt₀ is satisfied and
the condition of Δt₁/t₀≧0.6 is also satisfied.

7. The method for manufacturing an aluminum alloy semifinished product for a hard disk drive device case body according to claim 1,
wherein hot forging is performed by applying back pressure to at least a part of the forging material in the first forging step.

8. The method for manufacturing an aluminum alloy semifinished product for a hard disk drive device case body according to claim 1,
wherein an Al—Si eutectic alloy including Si: 5% to 12% (mass %, the same applies hereafter), Fe: 0.1% to 1.0%, Cu: less than 1.0%, Mg: 0.3% to 1.5%, and a balance consisting of Al and unavoidable impurities is used as the aluminum alloy of the forging material.

9. The method for manufacturing an aluminum alloy semifinished product for a hard disk drive device case body according to claim 1,
wherein one alloy selected from a 6000 series alloy, 7000 series alloy, and 2000 series alloy is used as the aluminum alloy of the forging material.

10. The method for manufacturing an aluminum alloy semifinished product for a hard disk drive device case body according to claim 1,
wherein a 1000 series alloy is used as the aluminum alloy of the forging material.

11. An aluminum alloy semifinished product for a hard disk drive device case body which is manufactured by the method according to claim 1.
